(19) United States
(12) Patent Application Publication
(10) Pub. No.: US 2011/0232715 A1
(43) Pub. Date: Sep. 29, 2011

(54) MINIMALLY PENETRATING PHOTOVOLTAIC ASSEMBLY FOR USE WITH A SLOPED ROOF AND RELATED METHODS

(75) Inventors: Carl J.S. Lenox, Oakland, CA (US); Doug Rose, San Jose, CA (US); Michael Knuepfel, San Francisco, CA (US)

(73) Assignee: SunPower Corporation, San Jose, CA (US)

(21) Appl. No.: 12/732,649

(22) Filed: Mar. 26, 2010

(51) Int. Cl. H01L 31/042; B32B 43/00; B32B 37/02

(52) U.S. Cl. 136/244; 156/71

(57) ABSTRACT

An assembly which is lightweight includes an interconnected array of PV modules, where each PV modules is defined in part by a module outer perimeter portion. This array is defined in part by an outer perimeter portion including an upper edge portion, side edge portions, and a lower edge portion. The array is secured to a sloped roof along at least one of the upper or lower edge portion of the array. The assembly further includes interlocking features along the module outer perimeter portion which distribute uplift forces to adjacent PV modules. Additionally included is at least one wind deflector located along the lower edge of the array and non-penetrating base feet disposed on the sloped roof supporting at least a portion of the array.

### GOVERNMENT FUNDING

The invention described herein was made with government support under contract number DE-FC36-07GO17043 awarded by the United States Department of Energy. The United States Government may have certain rights in the invention.

### TECHNICAL FIELD

The application relates generally to a photovoltaic array. More particularly, it relates to a minimally penetrating photovoltaic assembly for use with a sloped roof.

### BACKGROUND

Currently, photovoltaic (PV) modules can be secured to roofs with rack systems that include vertical stanchions and lateral rails. In particular, the lateral rails are attached to the stanchions, which are typically several inches off the roof, and the PV modules are attached to the rails. Installations of PV modules using such traditional rack systems may be difficult because, for example, the installations can be very labor intensive due to the deficient designs of the stanchions and rails. Additionally, the stanchions may possibly penetrate deeply into the roof and/or in a large number of locations. For example, relatively large holes are often pre-drilled through the roofing material to accommodate the mounting hardware. Because of the size of these large holes, and/or the large number of penetrations, it is often difficult to tell if adequate waterproofing has been achieved. It should be appreciated that many of these traditional PV rack systems may often include one or more of the above-described drawbacks or other drawbacks not mentioned.

### SUMMARY

An assembly includes an interconnected array of photovoltaic (PV) modules, where each of the PV modules is defined in part by a module outer perimeter portion. The array is defined in part by an outer perimeter portion including an upper edge portion, side edge portions, and a lower edge portion. The interconnected array is configured to be secured to a sloped roof along at least one of the upper or lower edge portion of the array. The assembly further includes interlocking features along the module outer perimeter portion which distribute uplift forces to adjacent modules. Additionally included is at least one wind deflector located along the lower edge of the array and one or more non-penetrating base feet are configured to be disposed on the sloped roof, where the base feet supports at least a portion of the interconnected array of PV modules. Wind uplift forces on the array may be resisted through distribution of forces within the array, pressure equalization treatment, and/or aerodynamic treatment of the array.

A method includes mounting two or more PV modules on a sloped roof with non- penetrating roof mounting structure. The two or more PV modules are interconnected into an array of PV modules and at least a portion of an upper edge portion of the array is configured to be secured with the sloped roof. Additionally, at least one wind deflector is coupled with at least a portion of a lower edge portion of the array. The method further includes resisting wind uplift forces on the array through distribution of forces within the array, pressure equalization treatment, and/or aerodynamic treatment of the array.

These and other embodiments, aspects, advantages, and features will be set forth in part in the description which follows, and in part will become apparent to those skilled in the art by reference to the following description of embodiments of the invention and referenced drawings or by practice of the embodiments. The aspects, advantages, and features are realized and attained by means of the instrumentalities, procedures, and combinations particularly pointed out in the appended claims and their equivalents.

### BRIEF DESCRIPTION OF THE DRAWINGS

Embodiments of the invention may be best understood by referring to the following description and accompanying drawings which illustrate such embodiments. In the drawings:

FIG. 1 illustrates a block diagram of a photovoltaic system according to one or more embodiments.

FIG. 2 illustrates a side view of a photovoltaic system according to one or more embodiments.

FIG. 3 illustrates a perspective view of a photovoltaic module assembly according to one or more embodiments.

FIG. 4 illustrates a perspective view of a photovoltaic module assembly according to one or more embodiments.

FIG. 5 illustrates a perspective view of a portion of a photovoltaic module assembly according to one or more embodiments.

FIG. 6 illustrates a perspective view of a portion of a photovoltaic module assembly according to one or more embodiments.

FIG. 7 illustrates a side view of a portion of a photovoltaic module assembly according to one or more embodiments.

FIG. 8 illustrates a side view of a portion of a photovoltaic module assembly according to one or more embodiments.

FIG. 9 illustrates a bottom perspective view of a photovoltaic module assembly according to one or more embodiments.

FIG. 10 illustrates a bottom perspective view of a photovoltaic module assembly according to one or more embodiments.

FIG. 11 illustrates a perspective view of a base foot according to one or more embodiments.

FIG. 12 illustrates a bottom perspective view of a photovoltaic module assembly according to one or more embodiments.

FIG. 13 illustrates a bottom perspective view of a photovoltaic module assembly according to one or more embodiments.

FIG. 14 illustrates a bottom perspective view of a photovoltaic module assembly according to one or more embodiments.

FIG. 15 illustrates a top perspective view of a photovoltaic module assembly according to one or more embodiments.

FIG. 16 illustrates a top perspective view of a photovoltaic module assembly according to one or more embodiments.

FIG. 17 illustrates a top perspective view of a photovoltaic module assembly according to one or more embodiments.

FIG. 18 illustrates a top view of a photovoltaic module assembly according to one or more embodiments.

FIG. 19 illustrates a side view of a photovoltaic module assembly according to one or more embodiments.

### DESCRIPTION OF THE EMBODIMENTS

The following detailed description includes references to the accompanying drawings, which form a part of the detailed description. The drawings show, by way of illustration, specific embodiments in which the present photovoltaic assemblies and methods may be practiced. These embodiments, which are also referred to herein as “examples,” are described in enough detail to enable those skilled in the art to practice the present photovoltaic assemblies and methods. The embodiments may be combined, other embodiments may be utilized or structural or logical changes may be made without departing from the scope of the present photovoltaic assemblies and methods. The following detailed description is, therefore, not to be taken in a limiting sense, and the scope of the present photovoltaic assemblies and methods is defined by the appended claims and their legal equivalents.

In this document, the terms “a” or “an” are used to include one or more than one, and the term “or” is used to refer to a nonexclusive “or” unless otherwise indicated. In addition, it is to be understood that the phraseology or terminology employed herein, and not otherwise defined, is for the purpose of description only and not of limitation.

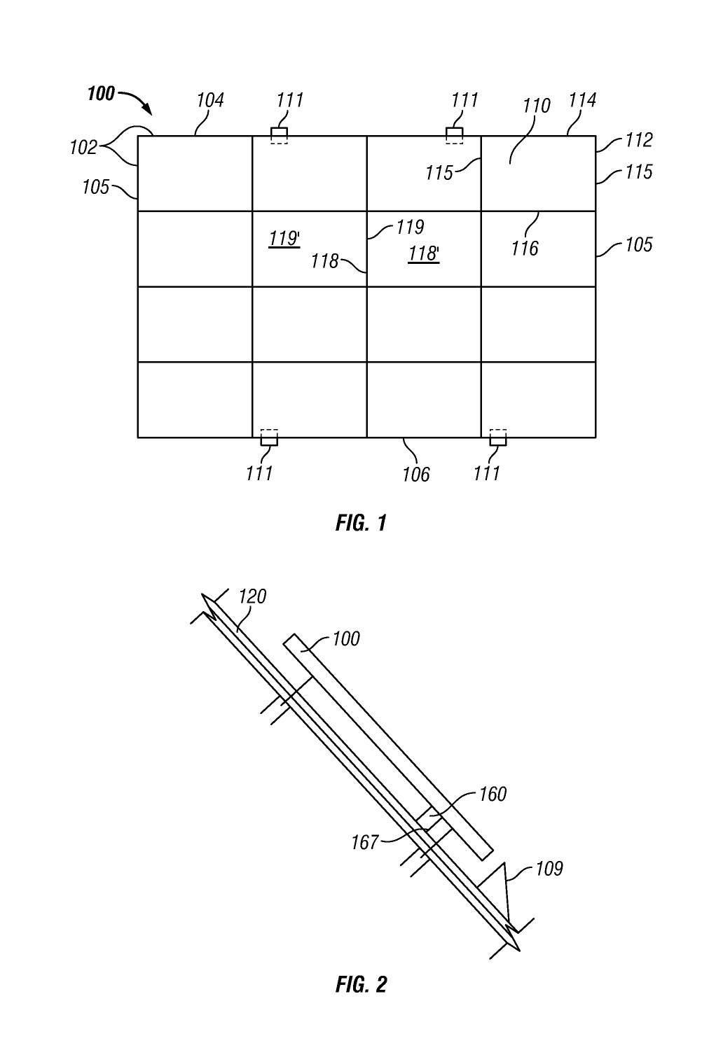

An assembly includes an interconnected array (or “array”) of photovoltaic (PV) modules, interlocking features, at least one wind deflector, and one or more non-penetrating base feet. In an option, the interconnected array, wind deflector, and base feet are collectively lightweight such that an average load on the roof does not exceed about 10 lb/sq. feet. For example, an average load of the lightweight structure is between about 2 lb/sq. feet and about 5 lb/sq. feet. In another example, an average load of the lightweight structure is about 2.5 lb/sq. feet. As used herein, the term “about” means that the specified dimension or parameter may be varied within an acceptable tolerance for a given design or application. In some embodiments, for example, an acceptable tolerance for a parameter is ±10%. FIG. 1 illustrates an example of an array 100 of individual PV modules 110. Each of the PV modules 110 are defined in part by a module outer perimeter portion 112, including an upper edge portion 114, side edge portions 115, and a lower edge portion 116. The array 100 is defined in part by an outer perimeter portion 102, an upper edge portion 104, side edge portions 105, and a lower edge portion 106.

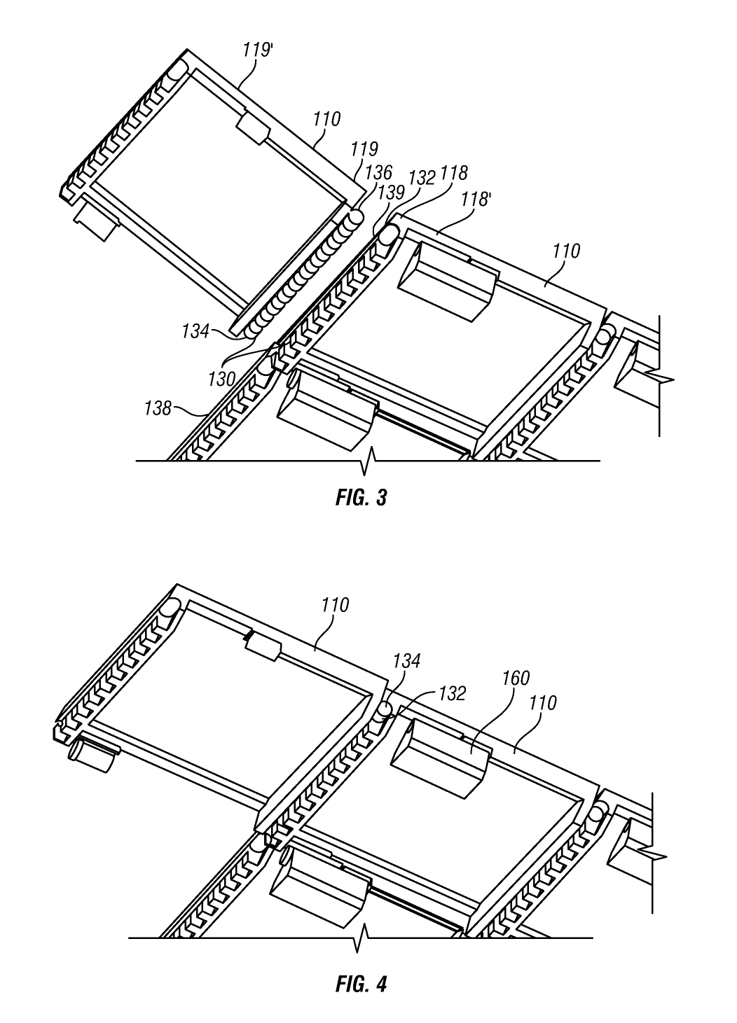

The array 100 of PV modules 110 are interconnected to one another with interlocking features 130, as depicted in FIG. 3. The interlocking features 130 are, in an option, disposed along the module outer perimeter portion which distributes uplift forces to adjacent PV modules 110. In an option, the interlocking features 130 are between adjacent PV modules 110 which planarize adjacent module edge portions. In a further option, the interlocking features 130 allow for a single PV module 110 to be removed without removal of an adjacent PV module 110. The array 100 is configured to be mounted on or secured to a sloped roof 120, for instance as shown in FIG. 2. The roof can have a slope, for example, of 1-in-12, or greater. In an example, the interconnected array 100 is coupled with the sloped roof 120 only along less than all edge portions 104, 105, 106 of the array 100. In an option, the interconnected array 100 is coupled with the sloped roof 120 only along at least one or the upper and lower edge portions 104, 106. In another option, the interconnected array 100 is coupled with the sloped roof 120 only along the upper edge portion 104. In an example, the array 100 is coupled with the sloped roof 120 with a penetrating member that penetrates the sloped roof 120 and is mechanically coupled with the array 100.

The array 100 of PV modules 110 may be subjected to wind uplift forces. In an option, wind uplift forces on the array 100 are resisted in one or more different manners. For instance, a majority of wind uplift forces may be resisted through distribution of forces within the array 100, pressure equalization treatment, and/or aerodynamic treatment of the array 100.

The distribution of forces within the array 100 includes, but is not limited to, the mechanical and structural interconnections between the individual PV modules 110. Pressure equalization treatment includes methods and/or structure which equalize pressure between the array 100 and the sloped roof 120 and above the array 100. For example, the array 100 can include air gaps between various components so that air can flow through it. Examples of such gaps include one or more gaps located between the individual PV modules 110, a perimeter gap located between one or more PV modules 110 and an outer deflector, and a gap located between the deflector and the lower edge of the array 100. In another option, pressure equalization is enhanced by promoting flow of air under the PV modules 110 while also limiting the volume of air that can exist in these regions. In a further option, the deflector is a wind deflector, which may be porous to allow for convective air flow between the array 100 and the sloped roof 120 and deflecting wind gusts above the array 100.

The aerodynamic treatment also assists in resisting a majority of wind uplift forces on the array 100. The aerodynamic treatment includes, but is not limited to wind deflectors 109, such as upper wind deflectors, side wind deflectors, or lower wind deflectors. The wind deflectors can be placed at any relatively large entry points to an underside of the array 100 to prevent wind penetration into the entry point. In an option, the wind deflectors are as tall as the tallest adjacent components in the array 100 to minimize drag forces on the array 100. In an option, the wind deflectors are sloped at an angle to reduce drag forces on the deflector. In a further option, a curb section is utilized to provide improved aerodynamic performance and aesthetics may also include compatible features so that the PV modules 110 can lock into the curb directly, for example either using a rotating or sliding motion. In a further option, at least one wind deflector is located along the lower edge of the array 100 so as to minimize aerodynamic drag and uplift on the array 100.

Still referring to FIG. 2, one or more non-penetrating base feet 160 are included and are defined in part by an upper portion and a lower portion. The base feet 160 can be made from foam, hard rubber, or other semi-flexible material, and optionally include features that allow for the PV modules 110 to slide on and off of the base feet 160. The base feet 160 can include a wide base at the lower portion with elastomeric material. The material can be over-molded on to a metal base. Optionally the base feet 160 are self-leveling feet, for example manually or automatically. For instance, the base feet 160 are optionally equipped with a height adjustment, such as a threaded rod, where the base feet 160 would be spun to adjust the height, even after the PV module 110 is installed into the array 100. Alternately, a worm drive mechanism could be provided in which case access would be from the sides. Finally, the base feet 160 could be equipped with a fixed bearing on a guide rod to prevent foot rotation, with adjustment provided by a rotating nut on a rod affixed to the PV module frame, rather than the base feet 160. In yet another option, the one or more base feet 160 are spring feet. The spring feet involve supports that effectively and automatically adjust to inconsistencies in the roof surface while still providing support to the PV module 110. The types of springs include, but are not limited to, coil springs, bellow springs, or leaf springs and are made from a variety of materials, such as metal or polymers.

The one or more base feet 160 are configured to be disposed, for example, in a non-penetrating and/or non-ballasted manner on the sloped roof 120, and the one or more base feet 160 support at least a portion of the interconnected array 100 of PV modules 110. In a further option, the base feet 160 comprise a majority of supporting structures of the array 100, where the base feet 160 include 50% or greater of the supporting structures of the array 100, not including the sloped roof 120. An adhesive 167 is optionally disposed between the base feet 160 and a roof surface of the sloped roof 120. The adhesive 167, such as a temporary adhesive, would allow for the base feet 160 to be laid out, without the base feet 160 sliding down the sloped roof 120 or without the base feet 160 moving when a PV module 110 is slid into place on top of the base feet 160. Once installed, the adhesive 167 may not be necessary since the weight of the PV modules 110, anchors on adjacent PV modules 110, or other locking mechanism would keep the base feet 160 in position.

The assembly including the array 100 includes interlocking features 130, which is depicted in FIG. 3, along the module outer perimeter portion 112 between adjacent PV modules 110, which planarize adjacent module edge portions 114, 115, 116. In a further option, the interlocking features 130 allow for a single PV module 110 to be removed without removal of an adjacent PV module 110.

In an example, as depicted in FIGS. 1 and 3, a first side 118 of a first PV module 118′ has a recessed attachment feature 132 and a second side 119 of a second PV module 119′ has a projection attachment feature 134, and the projection attachment feature 134 is received within the recessed attachment feature 132. The interlocking features 130 can be used, for example, to lock the first PV module 118′ with the second PV module 119′ such as by rotating the first PV module 118′ relative to the second PV module 119′, or by rotating the second PV module 119′ relative to the first PV module 118′. To unlock the first PV module 118′ from the second PV module 119′, the first PV module 118′ is slid relative to the second PV module 119′.

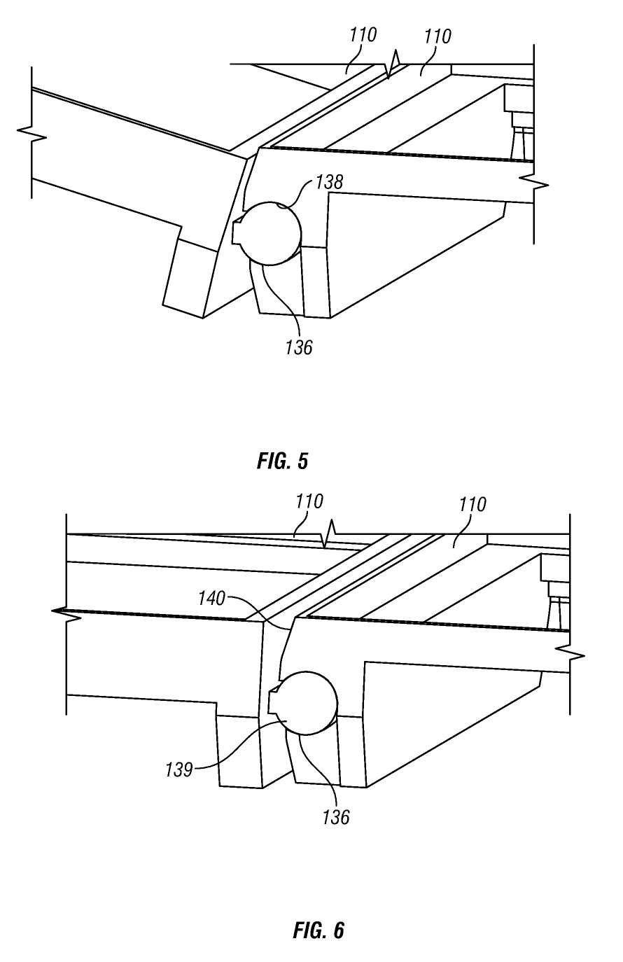

In an example as shown in FIGS. 3-6, a side of the PV module 110 features a series of rounded knobs 136. The opposite side of the PV module 120 has a rounded channel 138, which is complimentary to the rounded knob 136. Notches 139 cut into the channel 138 allow the knobs 136 from an adjacent PV module 110 to enter the rounded channel 138. In one embodiment, sliding the PV module 110 laterally (along the axis of the channel 138) moves the knobs 136 away from the notches 139. This lateral motion along the axis prevents the knobs 136 from becoming detached from the channel 138 of the adjacent PV module 120. Since the channel 138 and knobs 136 are concentric and have substantially equal diameters, the PV modules 110 are able to hinge up and down, adjusting to the contours of a sloped roof 120. As seen in FIG. 6, the side of the PV module 110 which includes the knob 136 has a frame that is substantially flat or planar. In an option, the side of the PV module 110 which includes the channel 138 has a frame that includes a chamfer 140. This limits the hinging motion of two adjacent PV modules 110. At the rotation limit, the flat frame edge and the chamfered frame edge butt up against each other. This feature limits the amount the PV modules 110 can rotate and greatly reduces the bending stress on the material between the knobs 136 and the frame when the PV modules 110 are at the rotation limit. The length and frequency of the knobs 136 can vary. The shorter the lengths of the knobs 136, the shorter the distance the PV modules 110 need to slide in order to be installed. For removing a PV module 110 from the middle of an array 100, limiting the slide distance required also minimizes the gap required from left to right between module rows, in an option, the knobs 136 and channels 138 can include a locking mechanism or tactile “click” that alerts the installer that the PV modules 110 have been slid over the proper amount and are installed correctly.

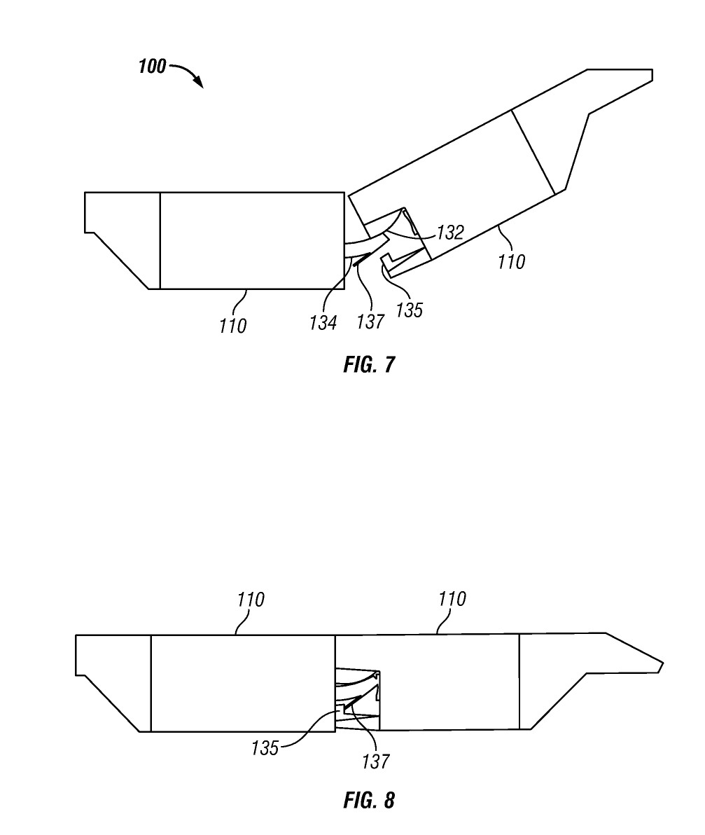

FIGS. 7-8 illustrate another example of an interconnected array 100 having interlocking features. The features include a projection attachment feature 134 and a recessed attachment feature 132. The projection attachment feature 134 is disposed within the recessed attachment feature 132 and the PV modules 110 are rotated and/or slid into place. To disengage the PV modules 110, one of the PV modules 110 is slid and an opening between recessed attachment features 132 and the projection attachment features 134 allow for disengagement of the projection attachment feature 134 from the recessed attachment feature 132. In yet another option, a clip can be used to interconnect the adjacent PV modules 110, where the clip can be slid into place.

In an option, a locking tab 135 is further included to prevent the PV module 110 from rotating back out of position as well as a bias member 137, such as a molded-in spring feature, to provide positive engagement in the joint between the adjacent PV modules 110. These features also provide positive feedback of proper engagement of the projection attachment feature 134. This type of feature may also be advantageous because bending down to engage PV modules 110 on a sloped roof 120 laterally can be difficult. Thee embodiments uses a more natural motion during placement that can be done from a standing position, and the features to help correct slight misalignment.

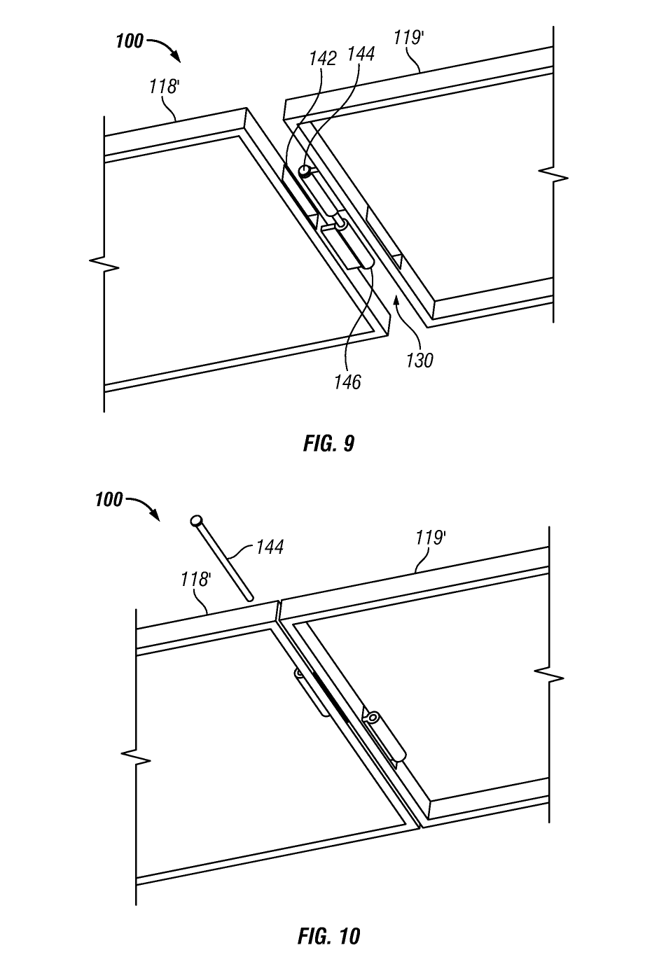

FIGS. 9-10 illustrate another example of an interconnected array 100 of PV modules 110. The interlocking features 130 include a flange 146 disposed on two adjacent PV modules 110. The flange 146 receives a pin 144 therein which interconnects the two adjacent PV modules 110. The PV module 110 further includes a cut out 142, which will further assist in the ability to remove a single PV module 110 without removal of an adjacent PV module 110. The cut out 142 is positioned on a first PV module 118′ to receive the flange 146 on a second PV module 119′ after the pin 144 is removed, as shown in FIG. 10. This increases the ability to laterally shift the PV modules 110 during the removal process, which could be particularly useful when removing a single PV module 110 from the middle on an array 100.

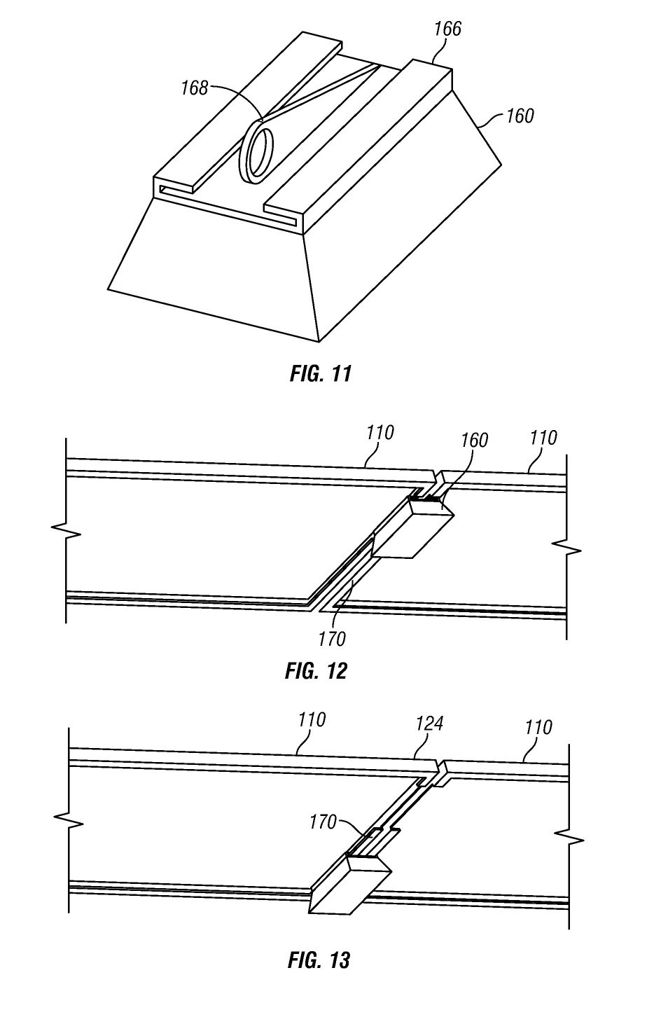

In another option, as shown in FIGS. 11-13, one or more of the base feet 160 are used to interconnect the PV modules 110 together. For example, the base foot 160 depicted in FIG. 11 includes interlocking features, such as a base coupler 166, which can extend from an upper portion of the base foot 160. The base coupler 166 interconnects with a first PV module and a second PV module (not shown) such that the first and second PV modules are interconnected via the base coupler 166 of the base foot 160. In an example, the base coupler 166 includes a lip that extends over a top portion of the base foot 160. As depicted below in FIGS. 12-13, the lip engages a flange 170 under adjacent PV modules 110.

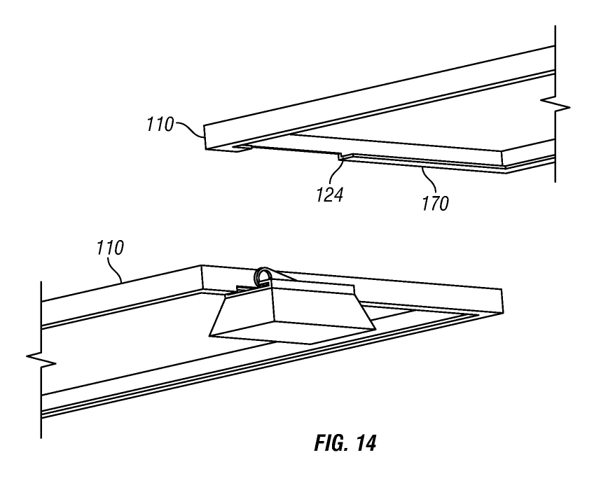

Returning to FIG. 11, a removal member 168 is disposed along a top portion of the base foot 160, where the removal member 168 is disposed between adjacent PV modules 110. In an example, the removal member 168 is a hook or hoop structure that extends upward from the base foot 160. The removal member 168 can be accessed even after PV modules 110 have been installed over the base foot 160. This would allow a broken PV module 110 to be removed from the center of an array 100 without having to remove adjacent PV modules 110. A repair person could simply use a device such as hooked pole to pull on the removal member 168 to move the base foot 160 back to a position where the lip does not engage flange, which would allow the PV module 110 on top of it to be removed, as shown in FIG. 14. The device could include a long pole would assist in overcoming the forces to keep the base foot 160 in place, such as friction and glue between base foot 160 and a sloped roof 120 in conjunction with the weight of the PV modules 110 and the weight of a repair person on top of the supports. After replacing the PV module 110, the pole and hook could be used to slide the base foot 160 back to the locked position.

FIGS. 12 and 13 show an example of how the PV modules 110 are installed. The base feet 160 are placed on the sloped roof 120 at measured intervals. The PV modules 100 are placed on top of the base feet 160. The PV modules 110 include a cut out 124, allowing for PV modules 110 to be placed in the base feet 160, as shown in FIG. 12, and for the lip to be slid over the flange 170 of adjacent PV modules 110, and locked into place, as shown in FIG. 13. In the installed position (FIG. 13), the PV module's movement is restricted in the upward and side-to-side directions. Forward and aft movement of the base foot 160 can be resisted either through the weight of the PV modules 110 preventing movement, or a locking mechanism that engages when the base foot 160 is moved into position, or a combination thereof. Asphalt shingle and other roofing materials are often uneven and very high-friction, making it difficult to slide and adjust PV modules 110 that are placed directly on top of a sloped roof's surface. This can be a problem during installation in attempting to make mechanisms line up or engage with adjacent PV modules 110. Placing the base feet 160 between the sloped roof 120 and the PV module 110 allows a metal to metal or metal to plastic contact surface (between the bottom of the PV module 110 and the top of the base feet 160) for the PV module 110 to easily slide, adjust, and line up with adjacent module attachment mechanisms.

To ease installation, the bottom of the base feet 160 could be coated with a glue or adhesive 167. The adhesive 167 would allow for the base feet 160 to be laid out, without the base feet 160 sliding down a sloped roof 120 or without the base feet 160 moving when a PV module 110 is slid into place on top of it. Once installed, the weight of the PV modules 110, the anchors on adjacent PV modules 110, or a locking mechanism would keep the base feet 160 in place. The adhesive 167 would no longer be necessary in maintaining the structural integrity of the array 100 and therefore would not need to be weather resistant.

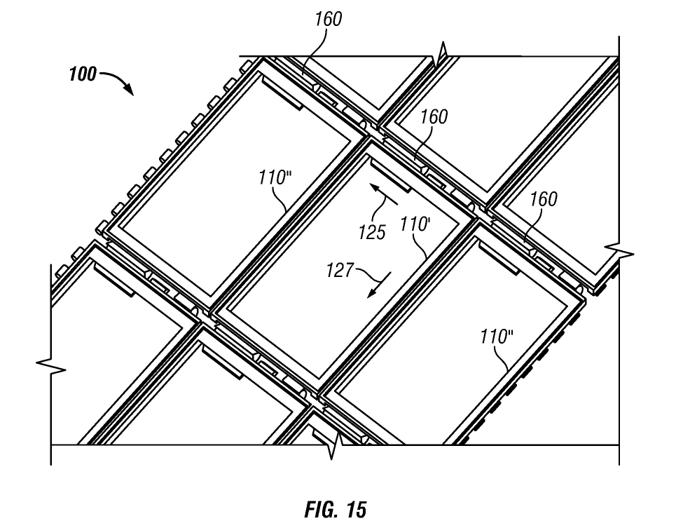

FIGS. 15-17 illustrate another example of an interconnected array 100, including various embodiments discussed above and below, and how the embodiments can be used together to allow a single PV module 110′ to be removed from an interlocking array 100 without having to remove an adjacent PV module 110″. In the example, PV module 110′ is to be removed from the array 100, for instance in the event the PV module 110′ is damaged. In FIG. 15, the base feet 160 for the PV module 110′ and adjacent PV modules 110″ are slid in the direction shown as 125 to unlock the PV modules 110, 110′ to not restrict movement of the PV modules 110, 110′.

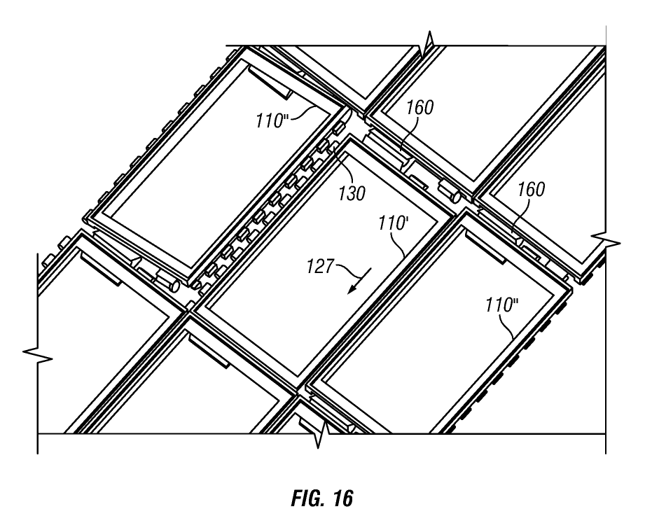

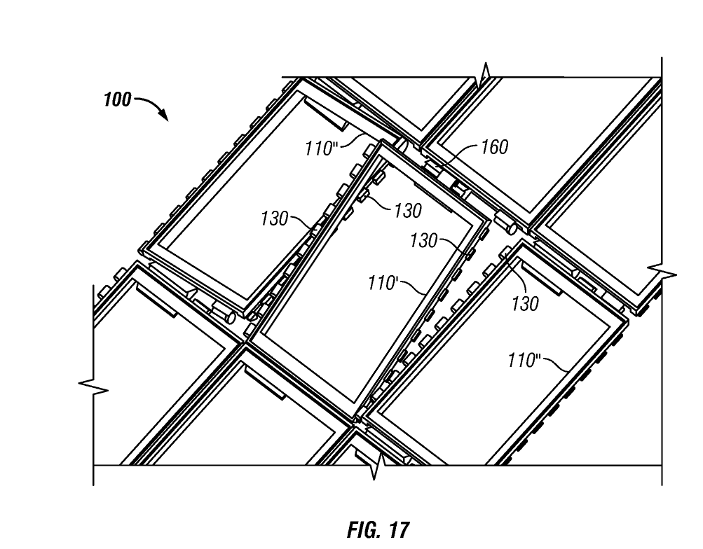

The PV module 110′ is shift in the direction shown as 127, and a cut out in adjacent PV module 110″ allows the PV module 110′ to be shifted further for removal. As PV module 110′ is slid, the interlocking features, such as the projection attachment features and recessed attachment features, can be disengaged from one another. As shown in FIG. 16, an adjacent PV module 110″ is slightly shifted, or swung upwards away from the sloped roof 120, and PV module 110′ can be removed from the array 100 as further shown in FIG. 17. The PV module 110′ is removed, and can be replaced with a new PV module 110. To install the new PV module 110, the steps above for removing the PV module 110 are followed, but in reverse order.

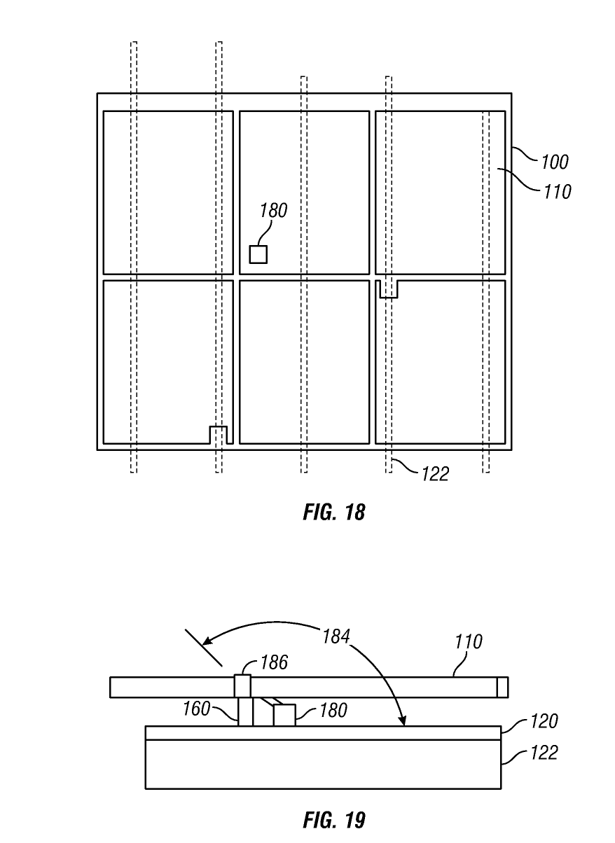

Referring to FIGS. 18 and 19, an assembly includes an interconnected array 100 of PV modules 110, each of the PV modules 110 defined in part by a module outer perimeter portion 112. The interconnected array 100 is interconnected as discussed above. The interconnected array 100 is coupled with a sloped roof 120. One or more base feet 160 are disposed in a non-penetrating and non-ballasted manner on the roof deck, where the one or more base feet 160 supporting at least a portion of the interconnected array 100 of PV modules 110. In an option, the one or more base feet 160 are disposed along an upper edge portion of the array 100. In one embodiment, this interconnected array 100 also has interlocking features such that, for example, the base feet 160 provide support (or resistance forces) to multiple PV modules 110 that are interconnected.

The assembly further includes one or more penetrating members 180 coupled with the sloped roof 120. The penetrating members 180 can be placed along a rafter 122 under the roof surface for increased hold-down form, or attached to the roof decking independent of rafter location. This allows for positioning of the penetrating members 180 to be independent of the placement of the PV modules 110. In a further option, the one or more penetrating members 180 are offset from the module outer perimeter portion. In another option, the penetrating members 180 are disposed within a footprint of the array 100, along the outer perimeter portion of the array 100, or combinations thereof. In yet another option, the penetrating members 180 are coupled with the sloped roof 120 and the array 100, for example with at least one tie down.

The tie down, such as a flexible tie down, is coupled with the one or more penetrating members 180, and further with a portion of the array 100, such as a PV module 110, at an attachment point. The tie down can go through slots in a frame of the PV module 110, allowing for attachment, or detachment from the PV module 110. The tie down can be a cable, wire, conductive or non-conductive element. An optional tie down tightening member 186 can also be included. For example, the tie down is pulled though slots and then into a screw, which when turned takes up the remainder of slack in the tie down. Since the location of the penetrating members 180 is independent of the placement of the PV modules 110, the tie down 182 is not necessarily perpendicular relative to the surface of the sloped roof 120. For instance, in an option, an angle 184 formed between the tie down 182 and the sloped roof 120 is obtuse.

The penetrating members 180 may, for example, be placed with a much larger spacing tolerance than is typical of those used in PV mounting systems, while still providing uplift resistance needed to keep the array 100 intact. The embodiments may, for example, provide a low cost method of attaching some points within an array 100 to the sloped roof 120 to prevent upward wind forces from lifting PV modules 110 from the sloped roof 120 or overstressing inter-module connections. By using a flexible tie down, such as a cable or wire, the resulting force on the joiner is only slightly higher than that of the upward wind force, but the low-cost attribute of non-precision alignment of the fixture is maintained.

Methods of installing and/or uninstalling the various arrays 100, PV modules 110 and the various embodiments and options discussed and shown are further discussed herein. The method includes mounting two or more PV modules 110 on a sloped roof 120 with minimally penetrating and lightweight roof mounting structure. What is meant by minimally penetrating is that the penetrating structures are not the primary structures used to hold the array 100 to the sloped roof 120. Other mechanisms, such as pressure management, or wind uplift management are used to keep the array 100 on the sloped roof 120. The assembly may also be lightweight, as discussed above. In an option, mounting the PV modules 110 includes disposing the PV modules 110 in a horizontal row of PV modules 110, and disposing an interlock between adjacent PV modules 110. To remove a PV module 110, the interlock is removed and a first PV module is slid relative to the adjacent PV module. The method includes securing at least a portion of an upper edge portion of the array 100 with the sloped roof 120.

The method further includes interconnecting the two or more PV modules 110 into an array 100 of PV modules 110 which planarize adjacent module edge portions. In an option, interconnecting the PV modules 110 include inserting a projection attachment feature of a first PV module into a recessed attachment feature of a second PV module and rotating the first PV module relative to the second PV module. The method further optionally includes removing at least one individual PV module 110 from an array 100 of interconnected PV modules 110 without removing surrounding PV modules 110. In an option, removing the at least one individual PV module 110 includes sliding a first PV module relative to a second PV module.

Several options for the method are as follows. For instance, the method includes locking a first PV module relative to a second PV module, for instance by rotating the first PV module relative to the second PV module. In a further option, the method includes disposing adhesive 167 between the roof mounting structure and a surface of the sloped roof 120, or a height of the roof mounting structure. In yet another option, the method includes securing the array 100 to the sloped roof 120 with a tie down, such as a tie down cable, including securing the tie down cable with the array 100 and a penetrating member coupled with the sloped roof 120.

The disclosed embodiments discuss various methods of interconnecting and securing PV modules 110 to sloped roofs 120. These methods incorporate pressure equalization effects to, for example, reduce wind loading. The embodiments may also provide a reduction in the number and penetrations into the sloped roof 120, and create the ability to remove an individual PV module 110 for maintenance or replacement without disturbing surrounding PV modules 110. The embodiments further allow for both portrait and landscape module orientation. Although developed with sloped roof applications in mind, many of these concepts are equally applicable to flat or low-slope roofs.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It is to be understood that the above description is intended to be illustrative, and not restrictive. For instance, any of the aforementioned examples may be used individually or with any of the other examples. Many other embodiments may be apparent to those of skill in the art upon reviewing the above description. The scope of the present PV assemblies and methods should, therefore, be determined with reference to the appended claims, along with the full scope of legal equivalents to which such claims are entitled. In the appended claims, the terms “including” and “in which” are used as the plain-English equivalents of the respective terms “comprising” and “wherein.” Also, in the following claims, the terms “including” and “comprising” are open-ended, that is, a system, assembly, article, or process that includes elements in addition to those listed after such a term in a claim are still deemed to fall within the scope of such claim.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, various features may be grouped together to streamline the disclosure. This method of disclosure is not to be interpreted as reflecting an intention that the claimed embodiments require more features than are expressly recited in each claim. Rather, as the following claims reflect, inventive subject matter may lie in less than all features of a single disclosed embodiment. Thus, the following claims are hereby incorporated into the Detailed Description, with each claim standing on its own as a separate embodiment.

What is claimed is:

1. An assembly comprising:
an interconnected array of photovoltaic (PV) modules, each of the PV modules defined in part by a module outer perimeter portion, the interconnected array defined in part by an outer perimeter portion including an upper edge portion, side edge portions, and a lower edge portion, the interconnected array configured to be secured to a sloped roof along at least one of the upper or lower edge portion of the interconnected array;
interlocking features along the module outer perimeter portion which distribute uplift forces to adjacent PV modules;
at least one wind deflector located along the lower edge portion of the interconnected array; and
one or more non-penetrating base feet configured to be disposed on the sloped roof, the one or more base feet supporting at least a portion of the interconnected array of PV modules.

2. The assembly as recited in claim 1, wherein wind uplift forces on the interconnected array are resisted through at least one of distribution of forces within the interconnected array, pressure equalization treatment, or aerodynamic treatment of the interconnected array.

3. The assembly as recited in claim 1, wherein the interlocking features are between adjacent PV modules which planarize adjacent module edge portions, the interlocking features allowing for a single PV module to be removed without removal of an adjacent PV module.

4. The assembly as recited in claim 1, wherein the wind deflector has a gap between the wind deflector and the lower edge allowing for air flow between the interconnected array and the roof.

5. The assembly as recited in claim 1, wherein the wind deflector is a porous wind deflector allowing convective air flow between the interconnected array and the roof and deflects wind gusts above the interconnected array.

6. The assembly as recited in claim 1, wherein the interconnected array, wind deflector, and the base feet are collectively lightweight such that an average load on the roof does not exceed about 10 lb/sq feet.

7. The assembly as recited in claim 1, wherein the interconnected array is configured to be secured to the sloped roof with penetrating members.

8. The assembly as recited in claim 1, wherein the interconnected array includes at least a number of the PV modules having a gap between adjacent PV modules.

9. The assembly as recited in claim 1, wherein the base feet are non-ballasted base feet.

10. The assembly as recited in claim 1, further comprising penetrating members coupled with the sloped roof and the interconnected array, the penetrating members disposed within a footprint of the interconnected array, along the outer perimeter portion of the interconnected array, or combinations thereof.

11. The assembly as recited in claim 1, wherein the sloped roof has a slope greater than 1-in-12.

12. The assembly as recited in claim 1, further comprising at least one wind deflector located along at least one of the upper edge portion or the side edge portions.

13. The assembly as recited in claim 1, wherein the one or more base feet are self-leveling feet.

14. The assembly as recited in claim 13, wherein the one or more base feet include elastomeric material.

15. The assembly as recited in claim 13, wherein the one or more base feet are spring feet.

16. The assembly as recited in claim 1, wherein a first side of a first PV module has a recessed attachment feature, a second side of a second PV module has a projection attachment feature, and the projection attachment feature is received within the recessed attachment feature.

17. The assembly as recited in claim 1, further comprising adhesive disposed between the base feet and a roof surface.

18. The assembly as recited in claim 1, wherein the one or more base feet are defined in part by an upper portion and a lower portion, and a coupler extends from the upper portion.

19. The assembly as recited in claim 1, wherein a first PV module is rotatably lockable with a second PV module.

20. The assembly as recited in claim 1, wherein a first PV module is slidably unlockable with a second PV module.

21. The assembly as recited in claim 1, further comprising one or more penetrating members attached to the roof and forming a roof attachment location, and at least one flexible tie down connecting the one or more penetrating members with the interconnected array at an array attachment location, where the roof attachment location can be offset from the array attachment location.

22. An assembly comprising:
an interconnected array of photovoltaic (PV) modules, each of the PV modules defined in part by a module outer perimeter portion, the interconnected array defined in part by an outer perimeter portion including an upper edge portion and a lower edge portion, interlocking features along the module outer perimeter portion, the interconnected array configured to be coupled with a sloped roof;
one or more penetrating members configured to be coupled with the sloped roof and forming a roof attachment location;
at least one flexible tie down connecting the one or more penetrating members with the interconnected array at an array attachment location, where the roof attachment location can be offset from the array attachment location; and
one or more base feet disposed on the roof, the one or more base feet supporting at least a portion of the interconnected array of PV modules.

23. The assembly as recited in claim 22, wherein the one or more penetrating members are coupled with a rafter under a surface of the sloped roof.

24. The assembly as recited in claim 22, wherein the one or more penetrating members are offset from the module outer perimeter portion.

25. The assembly as recited in claim 22, further comprising a tie down tightening member.

26. The assembly as recited in claim 22, wherein a first PV module of the interconnected array is rotatably lockable with a second PV module of the interconnected array.

27. The assembly as recited in claim 22, wherein a first PV module of the interconnected array is slidably unlockable with a second PV module of the interconnected array.

28. The assembly as recited in claim 22, wherein the interlocking features allow for a single PV module to be removed without removal of an adjacent PV module.

29. A method comprising:
mounting two or more photovoltaic (PV) modules on a sloped roof with minimally- penetrating roof mounting structure;
interconnecting the two or more PV modules into an array of PV modules;
securing at least a portion of an upper edge portion of the array with the sloped roof;
coupling at least one wind deflector with at least a portion of a lower edge portion of the array; and
resisting wind uplift forces on the array through distribution of forces within the array, pressure equalization treatment, and aerodynamic treatment of the array.

30. The method as recited in claim 29, further comprising removing at least one individual PV module from an array of interconnected PV modules without removing surrounding PV modules.

31. The method as recited in claim 30, wherein removing the at least one individual PV module includes sliding a first PV module relative to a second PV module.

32. The method as recited in claim 29, wherein interconnecting the PV modules includes inserting a projection attachment feature of a first PV module into a recessed attachment feature of a second PV module, rotating the first PV module relative to the second PV module.

33. The method as recited in claim 29, further comprising interlocking a first PV module of the array with a second PV module of the array.

34. The method as recited in claim 29, further comprising disposing adhesive between the roof mounting structure and a surface of the sloped roof.

35. The method as recited in claim 29, further comprising securing a portion of the array to the sloped roof with a flexible tie down cable, including securing the tie down cable with the array and a penetrating member coupled with the roof top deck.

36. The method as recited in claim 29, wherein mounting the PV modules includes disposing the PV modules in a horizontal row of PV modules, and disposing an interlock between adjacent PV modules.

37. The method as recited in claim 36, further comprising removing the interlock and sliding a first PV module relative to the adjacent PV module.

38. An assembly comprising:
an interconnected array of photovoltaic (PV) modules, each of the PV modules defined in part by a module outer perimeter portion and having a gap between adjacent PV modules, the interconnected array defined in part by an outer perimeter portion including an upper edge portion and a lower edge portion, the interconnected array secured to a sloped roof along at least a portion of the upper edge portion of the interconnected array;
interlocking features along the module outer perimeter portion between adjacent PV modules;
at least one wind deflector located along the lower edge portion of the interconnected array; and
one or more non-penetrating base feet configured to be disposed on the sloped roof, the one or more base feet supporting at least a portion of the interconnected array of PV modules.
